(19) United States
(12) Patent Application Publication
(10) Pub. No.: US 2025/0389802 A1
(43) Pub. Date: Dec. 25, 2025

(54) Micro-Optics Module for Evaluating Optical Current Sensors and Method for its Manufacture

(71) Applicant: HSP Hochspannungsgeräte GmbH, Troisdorf (DE)

(72) Inventors: Thomas Judendorfer, Bamberg (DE); Stefan Schuberth, Lichtenfels-Schney (DE)

(21) Appl. No.: 18/877,774

(22) PCT Filed: Jun. 29, 2023
(86) PCT No.: PCT/EP2023/067825

§ 371 Date: Dec. 20, 2024

(30) Foreign Application Priority Data
Jul. 4, 2022 (DE) 10 2022 206 785.1

(51) Int. Cl. G01R 35/00; G01R 15/22; G01R 19/00

(52) U.S. Cl. CPC G01R 35/00; G01R 15/22; G01R 19/0092

(57) ABSTRACT

The invention relates to a micro-optics module (1) for evaluating optical current sensors and its manufacture as well as a method for populating printed circuit boards, wherein the micro-optics module (1) has at least one housing (2), which comprises at least one predefined holder (3) for at least one optical and/or electro-optical component (4). The at least one housing (2) with the at least one predefined holder (3) is produced by means of 3D printing.

The invention relates to a micro-optics module for evaluating optical current sensors, and the production thereof, as well as a method for populating circuit boards, wherein the micro-optics module comprises at least one housing which comprises at least one pre-defined holder for at least one optical and/or electro-optical component.

The manufacture of electronic assemblies and modules is possible in a simple and cost-effective manner in large numbers and good quality, by hand and semi-and fully automatically. In this case, circuit boards, in particular printed circuit boards (PCB), can be populated with electrical components such as resistors, capacitors and other electronic components. Photodiodes, which convert light into electrical current and are accommodated in standard housings, likewise do not represent a problem for modern circuit board populating machines. However, only simple binary or analogue intensity measurements can be carried out using photodiodes.

More complex optical structures, which include e.g. beam splitting, polarimetric filtering, interference filters, optical fiber coupling, cannot be produced directly on a circuit board by populating machines or by hand, in good quality. These are implemented separately from the circuit boards, in a separate, highly precise optical structure. For optical components, extremely exact holding or fixing, sometimes temperature-compensated, is required. This leads to high material and production costs, which result in high product costs. Therefore, in the case of low-cost products, the use of optical structures is omitted if possible.

If optical sensors are required, then only those which reduce the property to be detected to an intensity measurement are used. This also applies for optical current sensors. As a result, the functional scope of the assemblies and/or modules is limited.

Measuring instruments which use optical elements internally are constructed either according to the principle of free beam optics or of fiber optics. If the free beam optics method is used, then any optical structure can be achieved which does not exceed a size specified for the product. For these structures, optical components are used that are large and heavy compared with microelectronics, the material value of which components is very high. The production of structures in free beam optics takes place in dust-reduced cleanrooms. It requires very high-cost precision, optomechanical holders, which are adjusted to micrometer precision by technically skilled staff in laborious production processes.

A second possibility, the use of fiber optics, is a development of free beam optics. In this case, the handling of the very sensitive optical fibers is time-consuming and also requires trained staff. Furthermore, not all optical components can also be used as fiber optic components or can be obtained from suppliers in reproducible quality. The fibers and the available optical components are very sensitive to temperature and impact, since the light beam extends in an optical medium which changes its optical properties in the case of pressure and temperature changes. If the light beam travels over long distances in an optical fiber, then these effects become ever more pronounced, which leads to a high susceptibility to error.

Both methods of achieving optical structures are incompatible with populating of electronic circuit boards.

The object of the invention is that of specifying a micro-optics module, a method for the production thereof, and a method for producing a circuit board, which solve the problems described above. In particular, the object is that of specifying a simple, cost-effective, stable micro-optics module, specifying a simple possibility for producing the micro-optics module, and specifying the use thereof in connection with circuit boards.

The object is achieved according to the invention by a micro-optics module for evaluating optical current sensors having the features of claim 1, a method for producing a micro-optics module for evaluating optical current sensors, in particular a micro-optics module as described above, according to claim 11, and/or a method for producing a circuit board comprising an above-described micro-optics module according to claim 12. Advantageous embodiments of the micro-optics module according to the invention for evaluating optical current sensors are specified in the dependent claims. In this case, subjects of the main claim can be combined with features of dependent claims, and features of the dependent claims can be combined with one another.

A micro-optics module according to the invention for evaluating optical current sensors comprises at least one housing, which comprises at least one predefined holder for at least one optical and/or electro-optical component. The at least one housing, with the at least one pre-defined holder, is produced according to the invention by 3D printing.

The 3D printing makes it possible to provide, in a simple and cost-effective manner, a stable housing having at least one predefined holder or having predefined holders for optical and/or electro-optical components, for a micro-optics module for evaluating optical current sensors. The 3D printing makes it possible to produce holders in the housing for components with high precision and little deviation, in a simple and cost-effective manner, which comply with the high demands of the adjustment of optical and/or electro-optical components. Complex readjustment and setting by hand by highly qualified, expensive staff can be omitted.

The at least one housing can be made of a metal and/or comprise metal, in particular aluminum, steel, copper, bronze and/or tungsten carbide. These materials are temperature-resistant, exhibiting little volume change in the case of temperature changes, are mechanically and long-term stable, are cost-effective, and can be processed easily by means of 3D printing.

The at least one housing can comprise at least one device for fastening on circuit boards, in particular for manual and/or automatic populating of circuit boards. This allows for simple, cost-effective populating of circuit boards with the micro-optics module, in particular by hand, semi-automatically and/or fully automatically.

The housing can be configured as an SMD or a through-hole component for manual and/or automatic populating of circuit boards. This allows for simple, cost-effective production of circuit boards populated with the micro-optics module, without the need for readjustment of optical and/or electro-optical components on the circuit board, with the advantages described above.

The housing may comprise a micro-optics module having at least one optical and/or electro-optical component. The micro-optics in the housing can be manufactured in a simple and cost-effective manner, without complex readjustment of individual optical and/or electro-optical components since the holders can be produced in 3D printing without significant production deviations or errors. Thus, the micro-optics modules can be produced in a simple and cost-effective manner and can be easily further processed, e.g. in the populating of circuit boards.

The housing may comprise at least one optical filter, at least one optical lens, at least one beamsplitter plate and/or at least one polarization beamsplitter as the optical component. The housing may comprise at least one light emitter, in particular an LED, and/or at least one electro-optical sensor, in particular a photodiode, as the electro-optical component. Using such components, micro-optics can be produced in a simple and cost-effective manner, having a large functional scope, in particular for optical current measurement.

The housing may comprise at least one holder for an optical fiber. In this way, optical signals, in particular in the case of a current measurement, can be easily and reliably coupled into and/or out of the micro-optics module.

The housing may have dimensions, in particular height, length and width, in the millimeter range up to a few centimeters, e.g. in the range of 1 to 10 millimeters and/or in the range of from 1 millimeter to 10 centimeters. Thus, the dimensions of the micro-optics module are in ranges which fit well onto circuit boards.

The micro-optics module can have a weight in the gram range, in particular in the range of 1 to 100 grams. Thus, no significant oscillations and movements of the micro-optics module, in particular on a circuit board, are possible, which can lead to damage or even destruction. Small masses correspond to low use of material, which is associated with low costs. Disadvantages of optical structures having high masses and large dimensions, as described above, can be avoided in this way.

A method according to the invention for producing a micro-optics module for evaluating optical current sensors, in particular a micro-optics module described above, having at least one housing which comprises at least one pre-defined holder for at least one optical and/or electro-optical component, comprises production of the at least one housing with the at least one pre-defined holder by 3D printing.

A method according to the invention for producing a circuit board which comprises at least one micro-optics module as described above comprises populating the circuit board with the at least one micro-optics module, in particular configured as an SMD or a through-hole component, by hand and/or using at least one populating machine.

The advantages of the method according to the invention for producing a micro-optics module for evaluating optical current sensors, in particular a micro-optics module as described above, according to claim 11, and the advantages of the method according to the invention for producing a circuit board comprising at least one micro-optics module as described above, according to claim 12, are analogous to the above-described advantages of the micro-optics module according to the inventio for evaluating optical current sensors according to claim 1, and vice versa.

In the following, embodiments of the invention are shown schematically in the figures and described in greater detail below.

In the figures

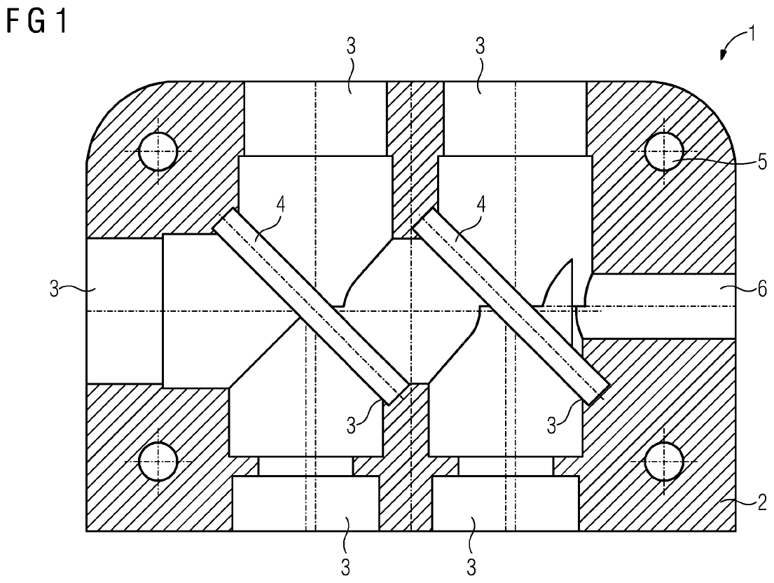

FIG. 1 is a schematic view of a micro-optics module 1 according to the invention for evaluating optical current sensors, comprising holders 3 for optical and/or electro-optical components 4 in a housing, produced by 3D printing, and

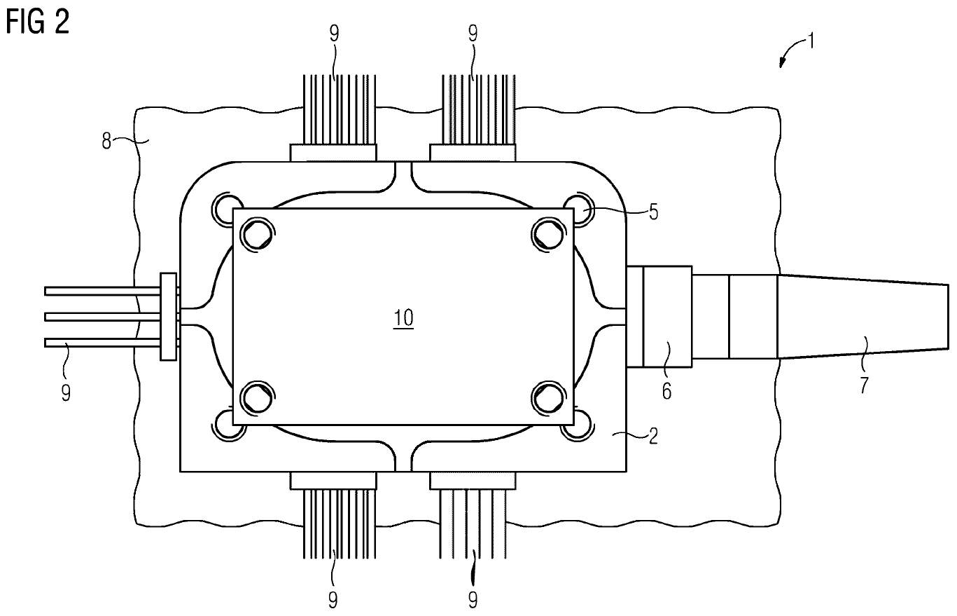

FIG. 2 is a schematic view of the micro-optics module 1 of FIG. 1, comprising a cover 10, optical fiber 7 and terminals 9 for electro-optical components 4, arranged on a circuit board 8.

FIG. 1 is a schematic plan view of a micro-optics module 1 according to the invention for evaluating optical current sensors. The micro-optics module 1 comprises a housing 2 which can be easily produced by 3D printing, in particular very precisely with respect to its dimensions, with low production tolerances, and at low cost as well as with little effort. The housing 2 is made e.g. of a metal and/or comprises a metal, in particular aluminum, steel, copper, bronze and/or tungsten carbide, which results in high mechanical stability, in particular long-term stability, having a stable shape, even in the case of temperature changes. Holders 3 for optical and/or electro-optical components 4 are formed in the housing 2.

The high mechanically and temperature-stable shape of the housing 2 allows for precise, in particular aligned, holding or bearing and/or arrangement of the optical and/or electro-optical components 4 in the housing 2. A readjustment, which is costly in terms of time and staff, is omitted. Optical components 4 are e.g. optical filters, optical lenses, beamsplitter plates or beamsplitters, and/or polarization beamsplitters or polarization filters. Electro-optical components 4 are e.g. light emitters, in particular LEDs, and electro-optical sensors, in particular photodiodes. These are configured e.g. as micro-optics, i.e. in small dimensions, in particular in the range of millimeters up to a few centimeters, and with a low weight, in particular in the range of one to several grams. A housing 2, which is also configured having small dimensions, i.e. measurements, in particular of height, length and width, e.g. in the millimeter range up to a few centimeters, in particular in the range of 1 to 10 millimeters and/or in the range of 1 millimeter to 10 centimeters, and having a weight e.g. in the gram range, in particular in the range of 1 to 100 grams, allows for small and lightweight micro-optics modules 1.

Micro-optics modules 1 having measurements e.g. in the millimeter range up to a few centimeters, in particular in the range of 1 to 10 millimeters and/or in the range of 1 millimeter to 10 centimeters, and having a weight e.g. in the gram range, in particular in the range of 1 to 100 grams, can be installed or arranged on circuit boards 8. The low weight means that circuit boards 8 are impaired only slightly in the case of vibrations by the micro-optics modules 1, and damage or even destruction of the populated circuit boards 8 can be prevented. Populating or arranging micro-optics modules 1 on a circuit board 8 is carried out e.g. by hand or using a populating machine. For this purpose, the micro-optics modules 1 are configured e.g. as an SMD (surface mounted device) and/or as a through-hole component, i.e. e.g. having a device 5 for fastening the micro-optics modules 1 on a circuit board 8. The device 5 comprises e.g. solder joints and/or drilled holes or through-holes, via which the micro-optics modules 1 can be arranged or positioned and/or fastened on the circuit board 8, e.g. by soldering, riveting, bolting and/or screwing.

FIG. 2 is a schematic view of the micro-optics module 1 of FIG. 1, comprising a cover 10, an optical fiber 7 and terminals 9 for electro-optical components 4. In the embodiment of FIG. 2, the micro-optics module 1 is arranged on a circuit board 8. An optical signal to be processed, in particular for current measurement, is coupled or fed into the micro-optics module 1 e.g. via an optical fiber 7, the end of which is arranged in a holder 6 formed in the housing 2.

The holders 3 already integrated in the housing 2 of the micro-optics module 1, for components 4 such as electro-optical sensors and optical components, i.e. in 3D printing with formed or predefined holders 3, make it possible in particular to already arrange electro-optical sensors with terminals 9 at defined locations, where e.g. terminals 9 can emerge from the housing 2 and can be electrically connected, in particular to electrical components of the circuit board 8, which, for the sake of simplicity, are not shown in the figures. Electrical circuits, in particular on the circuit board 8, for controlling and processing electrical signals of the electro-optical components 4, such as sensors and LEDS, arranged in or on the housing 2 of the micro-optics module 1, can be electrically connected to the electro-optical components 4 in this way. The optical parts or optical components 4 can be positioned sufficiently precisely, i.e. without adjustment, by the integrated optical holders 3, and contribute to the formation of predefined micro-optics. External optical sensors can be connected to the micro-optics. Externally connected optical sensors can receive an optical input signal, and their returned optical output signal can be coupled into the micro-optics again. In this case, the light signals or optical signals can optionally be conducted through further miniaturized optical components having different functionalities and can serve for the connection of optical sensors for current measurement, which are based e.g. on the Faraday effect.

FIG. 1 shows, by way of example, two optical components 4 in holders 3, e.g. in particular plate-shaped beamsplitters and/or polarization beamsplitters. As FIG. 2 shows, an optical fiber 7 is fastened in or on the housing 2 in a spatially defined and aligned manner, by means of a holder 6. A holder 3 for an electro-optical component 4, e.g. an LED, is arranged on the opposite side of the housing 2. FIG. 2 shows the electrical terminals 9 of the electro-optical component 4 by way of example as three bars. These can be connected to components of an electrical circuit on the circuit board 8. The circuit electrically actuates the electro-optical component 4, e.g. the LED, and the light generated by the LED is coupled into the optical fiber 7 in part, via the beamsplitter.

The optical fiber 7 passes beside an electrical conductor, the current flow of which is to be measured or determined and which, for the sake of simplicity, is not shown in the figures. The light of the LED in the optical fiber 7 is influenced or changed by the Faraday effect, in the event of current flow in the conductor through which current flows, depending on the current flow, e.g. the polarization of the light is changed, which was polarized e.g. while passing through the polarization beamsplitter. For example at a mirrored end of the optical fiber 7, which, for the sake of simplicity, is not shown in the figures, the light changed by the electrical current is reflected back and enters the micro-optics module 1 again via the optical fiber 7.

In each case two holders 3 for optical and/or electro-optical components 4 are arranged perpendicularly to the light axis between the LED and optical fiber 7, on two parallel axes, as shown in FIG. 1. Optical and/or electro-optical components 4 are arranged in the holders, as shown in FIG. 2. For example lenses, as optical components 4, can be arranged in the holders 3, in order to guide light out of the micro-optics module 1 to external electro-optical components, such as photodiodes, in particular on the circuit board 8. Alternatively or additionally or in combination, photodiodes, as optical components 4, can be arranged directly and in a spatially stable manner in the holders 3, in order to measure light or the intensity of light and convert this into electrical signals which are evaluated e.g. by components on the circuit board 8.

The light signal which emerges from the optical fiber 7 after being influenced by the current to be measured or determined, and is coupled or radiated into the micro-optics module 1, strikes the two plate-shaped beamsplitters and/or polarization beamsplitters, and is guided and/or reflected from there to two photodiodes for measurement or intensity determination. As a reference signal, light of the LED and/or polarized light before entry into the optical fiber 7 is guided and/or reflected through the two plate-shaped beamsplitters and/or polarization beamsplitters onto the two photodiodes opposite the first two photodiodes for measurement or intensity determination. This allows for a measurement of the output signal and the light signal influenced by the current, in particular an intensity measurement, which, converted into electrical signals, can be compared and/or evaluated by a corresponding electrical circuit on the circuit board 8.

As a result, the circuit on the circuit board 8 delivers an output signal, e.g. optically on a display and/or electrically for further processing, which corresponds to a standardized current measurement. The result can emerge e.g. by comparison of the output signal of the LED and/or of the polarized light in the optical fiber 7 with light from the optical fiber 7 after adjacently passing the conductor through which current flows, e.g. filtered after polarization or polarization change. The intensities are measured e.g. by photodiodes and processed by the electronic circuit in particular on the circuit board 8, e.g. by operational amplifiers, as electrical signals or pulses of the photodiodes, further processed by electronics, in particular on the circuit board 8, to a signal depending on the current to be measured. The current strength, in particular in the ampere up to the kiloampere range can be determined by gauging, in particular in high-voltage facilities.

The embodiments described above can be combined with one another and/or can be combined with the prior art. Thus, e.g. in addition to current further physical variables can also be measured, which change an optical signal. Further applications for micro-optics are possible. A very wide range of optical and/or electro-optical components 4 can be used for different arrangements and measurements. The structure, shown in the figures, of holders 3 in the housing 2 is merely by way of example, for one application. Other arrangements of holders 3 with different shapes and numbers of holders 3 for different components and applications are possible. The advantage of the 3D printing is that micro-optics modules 1 can be created in a simple and cost-effective manner for many possible fields of use, having stable holders, which allow for the arrangement of optical and/or electro-optical components in a simple and cost-effective and long-term stable manner, without the need of high staff costs for adjustment. The small size and the low weight allow for simple mounting e.g. on PCBs (printed circuit boards) or circuit boards, without the risk of destruction in the case of vibrations.

### LIST OF REFERENCE SIGNS

1 micro-optics module
2 housing
3 holder for optical and/or electro-optical components
4 optical and/or electro-optical component
5 device for fastening on circuit boards
6 holder for an optical fiber
7 optical fiber
8 circuit board
9 terminals of the electro-optical components
10 cover

1. A micro-optics module for evaluating optical current sensors, comprising at least one housing that further includes at least one predefined holder for any combination of an optical component and an electro-optical component, wherein the at least one housing is produced by 3D printing.

2. The micro-optics module according to claim 1, wherein the at least one housing is made of a metal or is comprised at least partially of metal.

3. The micro-optics module according to claim 1, wherein the at least one housing comprises at least one device for fastening the micro-optics module on circuit boards wherein the micro-optics module is configured for manual or automatic populating of the circuit board.

4. The micro-optics module according to claim 1, wherein the housing is configured as a surface-mounted device (SMD) or a through-hole component for manual or automatic populating of circuit boards.

5. The micro-optics module according claim 1, wherein the housing comprises includes a micro-optics having any combination of an optical and an electro-optical component.

6. The micro-optics module according to claim 1, wherein the housing comprises includes any combination of at least one optical filter, at least one optical lens, at least one beamsplitter plate and/or at least one polarization beamsplitter as the optical component.

7. The micro-optics module according to claim 1, wherein the housing comprises includes any combination of at least one light emitter, and at least one electro-optical sensor, as the electro-optical component.

8. The micro-optics module according to claim 1, wherein the housing comprises includes at least one holder for an optical fiber.

9. The micro-optics module according to claim 1, wherein the housing has each of a length, a width and a height of the housing are in a range of 1 millimeter to 10 centimeters.

10. The micro-optics module according to claim 1, wherein the micro-optics module has a weight in a range of 1 to 100 grams.

11. A method for producing a micro-optics module for evaluating optical current sensors, the method comprising:
3D printing at least one housing that further comprises at least one predefined holder for any combination of an optical component and an electro-optical component.

12. A method for producing a circuit board that includes at least one micro-optics module according to claim 1, the method comprising:
populating the circuit board with the at least one micro-optics module; and
configuring the circuit board as an SMD or a through-hole component, by using hand assembly or assembly using a populating machine.

13. The micro-optics module of claim 2, wherein the metal is any combination of aluminum, steel, copper, bronze and tungsten carbide.

14. The micro-optics module of claim 7, wherein the light emitter is a light-emitting diode (LED).

15. The micro-optics module of claim 7, wherein the electro-optical sensor is a photodiode.
